(19) United States
(12) Patent Application Publication
(10) Pub. No.: US 2005/0136670 A1
(43) Pub. Date: Jun. 23, 2005

(54) Compositions and methods for controlled polishing of copper

(76) Inventors: Joseph G. Ameen, Newark, DE (US); Raymond Lee Lavoie JR., Chesapeake City, MD (US); John Quanci, Haddonfield, NJ (US); Joseph K. So, Newark, DE (US); Terence M. Thomas, Newark, DE (US); Qianqiu Ye, Wilmington, DE (US)

Correspondence Address: Rodel Holdings, Inc.;Suite 1300, 1105 North Market Street, Wilmington, DE, 19899, US

(21) Appl. No.: 10/741,370

(22) Filed: Dec. 19, 2003

(51) Int. Cl. B24D 3/02; H01L 21/302; H01L 21/461

(52) U.S. Cl. 438/691

(57) ABSTRACT

The present invention provides an aqueous composition useful for polishing copper on a semiconductor wafer comprising by weight percent 0.001 to 6 inhibitor for a nonferrous metal, 0.05 to 10 complexing agent for the metal, 0.01 to 25 copper removal agent for accelerating the removal of the copper, 0.5 to 40 abrasive, 0 to 10 selected from the group comprising, polyvinylpyrrolidone, thermoplastic polymer and mixtures thereof, wherein the copper removal agent is imidazole.

### BACKGROUND OF THE INVENTION

The invention relates to chemical mechanical planarization (CMP) of semiconductor wafer materials and, more particularly, to CMP compositions and methods for removing interconnect metals from semiconductor wafers in the presence of dielectrics and barrier materials.

Typically, a semiconductor wafer has a wafer of silicon and a dielectric layer containing multiple trenches arranged to form a pattern for circuit interconnects within the dielectric layer. The pattern arrangements usually have a damascene structure or dual damascene structure. A barrier layer covers the patterned dielectric layer and a metal layer covers the barrier layer. The metal layer has at least sufficient thickness to fill the patterned trenches with metal to form circuit interconnects.

CMP processes often include multiple planarization steps. For example, a first step removes a metal layer from underlying barrier dielectric layers. The first step polishing removes the metal layer, while leaving a substantially smooth planar surface on the wafer with metal-filled trenches that provide circuit interconnects planar to the polished surface. First step polishing removes excess interconnect metals, such as copper, at an initial high rate. After the first step removal, the second step polishing can remove a barrier that remains on the semiconductor wafer. This second step polishing removes the barrier in the presence of a dielectric layer and metal interconnects.

Unfortunately, CMP processes often result in unwanted interconnect metals from inadequate second step polishing. In other words, the interconnect metal is not removed at a high enough rate during the second step polishing process. This unwanted metal can compromise electrical signals and impair continued fabrication of dual damascene structures. Hence, in some circumstances, certain chip manufacturers actually desire a high static etch rate for the interconnect metal in second step polishing to “tune” the rate for specific applications.

Tsuchiya et al., in U.S. Pat. No. 6,585,568, discloses a known composition for polishing copper comprising a benzotriazole and a triazole compound. The composition of Tsuchiya decreases the etching rate in an attempt to minimize dishing. Unfortunately, such known compositions may create unwanted copper, a condition known as “proud copper”.

Hence, what is needed is an improved CMP composition and method for controlling the polishing of metal interconnects. In particular, there is a need for a CMP composition and method for accelerating the removal of copper during second step polishing processes.

### STATEMENT OF THE INVENTION

In a first aspect, the present invention provides an aqueous composition useful for polishing copper on a semiconductor wafer comprising by weight percent 0.001 to 6 inhibitor for a nonferrous metal, 0.05 to 10 complexing agent for the metal, 0.01 to 25 copper removal agent for accelerating the removal of the copper, 0.5 to 40 abrasive, 0 to 10 oxidizer and 0 to 10 selected from the group comprising, polyvinylpyrrolidone, thermoplastic polymer and mixtures thereof, wherein the copper removal agent is imidazole.

In a second aspect, the present invention provides an aqueous composition useful for polishing copper on a semiconductor wafer comprising by weight percent 0.001 to 6 benzotriazole to inhibit corrosion of the copper, 0.05 to 10 complexing agent for the copper, 0.01 to 25 imidazole for accelerating the polishing of the copper, 0.5 to 40 abrasive, 0 to 10 oxidizer and 0 to 10 selected from the group comprising, polyvinylpyrrolidone, polyvinyl alcohol and mixtures thereof and balance water, wherein a weight percent ratio of the imidazole to the benzotriazole is at least 3 to 1.

In a third aspect, the present invention provides a method for polishing copper from a semiconductor wafer comprising: contacting the wafer with a polishing composition, the wafer containing the copper, the polishing composition comprising by weight percent 0.001 to 6 inhibitor for a nonferrous metal, 0.05 to 10 complexing agent for the metal, 0.01 to 25 imidazole, 0.5 to 40 abrasive, 0 to 10 oxidizer, 0 to 10 selected from the group comprising, polyvinylpyrrolidone, polyvinyl alcohol and mixtures thereof and balance water; and polishing the wafer with a polishing pad, wherein the imidazole accelerates the polishing of the copper.

### DETAILED DESCRIPTION

The composition and method provide excellent controlled polishing of copper. In particular, the aqueous composition of the present invention is useful for “tuning” the removal rate of the copper to suit a desired application. Namely, the present composition can be utilized to accelerate the removal of copper from a semiconductor wafer while minimizing corrosion problems. The composition utilizes a known inhibitor for copper, imidazole, to unexpectedly accelerate the copper removal.

In a preferred embodiment of the present invention, an imidazole (“copper removal agent”) is utilized in the composition to unexpectedly accelerate the removal of copper. Any imidazole (e.g., substituted, non-substituted) may be utilized in the present invention. For example, imidazole compounds represented by the following formulas (1), (2) may be utilized, 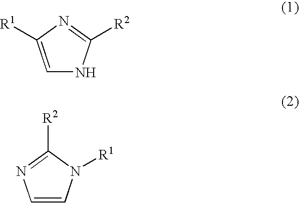
wherein, R¹ and R² is a hydrogen atom, an alkyl group optionally having substituent(s), an unsaturated alkyl group optionally having substituent(s), a cycloalkyl group optionally having substituent(s), an aralkyl group optionally having substituent(s), an arylalkenyl group optionally having substituent(s), an aryl-cyclic hydrocarbon group optionally having substituent(s), an aryl group optionally having substituent(s), a heterocyclic residue optionally having substituent(s) and an alkoxycarbonyl group optionally having substituent(s) and combinations thereof.

For purposes of this specification, the “alkyl group” may be a linear or branched alkyl group having 1 to 24 carbon atoms, such as methyl, ethyl, propyl, isopropyl, butyl, isobutyl, sec-butyl, tert-butyl, pentyl, hexyl, heptyl, octyl, nonyl, decyl, dodecyl, undecyl and the like.

The “unsaturated alkyl group” in the present invention may be a linear or branched unsaturated alkyl group having 2 to 24 carbon atoms, such as alkenyl (e.g., vinyl, 1-propenyl, 2-propenyl, isopropenyl, butenyl, pentenyl, hexenyl, heptenyl, octenyl, nonenyl, decenyl, dodecenyl, undecenyl and the like); and alkynyl (e.g., ethynyl, propynyl, butynyl, pentynyl, hexynyl, heptynyl, octynyl, nonynyl, decynyl, dodecynyl, undecynyl and the like).

The “cycloalkyl group” in the present invention may be a saturated or unsaturated cycloalkyl having 3 to 6 carbon atoms, such as cyclopropyl, cyclohexyl and the like.

The “aryl group” in the present invention may be phenyl, naphthyl, anthranyl and the like.

The “aralkyl group” in the present invention may be an aralkyl group having 7 to 24 carbon atoms, wherein the alkyl moiety is linear or branched. Examples thereof include benzyl, phenethyl, naphthylmethyl and the like.

The “arylalkenyl group” in the present invention can have 8 to 24 carbon atoms, wherein the aryl moiety is as defined for the above-mentioned aryl and the alkenyl moiety is linear or branched. Examples thereof include phenylethenyl, phenylpropenyl, phenylbutenyl, naphthylethenyl, naphthylpropenyl and the like.

The “aryl-cyclic hydrocarbon group” in the present invention can have 9 to 24 carbon atoms, wherein the aryl moiety is as defined for the above-mentioned aryl and the cyclic hydrocarbon moiety is saturated or unsaturated. Examples thereof include phenylcyclopropyl, phenylcyclopentyl, phenylcyclohexyl, naphthylcyclopropyl, naphthylcyclopentyl, naphthylcyclohexyl and the like.

The “heterocyclic residue” in the present invention can have an unsaturated 5- or 6-membered ring having 1 or more hetero atoms (e.g., nitrogen atom, oxygen atom, sulfur atom and the like). Examples thereof include furyl group, thienyl group, pyridyl group, pyrimidinyl group, quinolyl group and the like.

The “alkoxycarbonyl group” in the present invention can have a linear or branched alkoxycarbonyl group having 2 to 8 carbon atoms. Examples thereof include methoxycarbonyl, ethoxycarbonyl, propoxycarbonyl, butoxycarbonyl, isobutoxycarbonyl, sec-butoxycarbonyl, tert-butoxycarbonyl, pentyloxycarbonyl, hexyloxycarbonyl, heptyloxycarbonyl and the like, with preference given to methoxycarbonyl and ethoxycarbonyl.

The alkyl group, unsaturated alkyl group, cycloalkyl group, aralkyl group, aryl group, arylalkenyl group, aryl-cyclic hydrocarbon group and heterocyclic residue for R² are optionally substituted with 1 or more substituents. Examples of the substituent include linear or branched alkyl group having 1 to 12 carbon atoms (e.g., methyl, ethyl, propyl, isopropyl, butyl, isobutyl, sec-butyl, tert-butyl, pentyl, hexyl, heptyl, octyl, nonyl, decyl, dodecyl and the like), unsaturated alkyl group, halogen atom (fluorine atom, chlorine atom, bromine atom, iodine atom), linear or branched alkoxy group having 1 to 12 carbon atoms (e.g., methoxy, ethoxy, propoxy, isopropoxy, butoxy, isobutoxy, sec-butoxy, tert-butoxy, pentyloxy, hexyloxy, heptyloxy, octyloxy, nonyloxy, decyloxy, dodecyloxy and the like), carboxyl group, heterocyclic residue and the like.

Advantageously, the imidazole compound may be present in the solution in a range of concentrations, for example from 0.01 to 25 weight percent. This specification expresses all concentrations in weight percent. A single type of imidazole compound may be present, or a mixture of imidazole compounds may be used. More advantageously, the solution contains 0.05 to 10 weight percent imidazole compounds and for most applications, imidazole compound concentrations of 0.1 to 5 weight percent provide sufficient barrier removal rates. Most preferably, the concentration of the imidazole compound is 1 weight percent.

Advantageously, the solution contains 0.001 to 6 weight percent inhibitor to control copper removal rate by static etch or other removal mechanism. Adjusting the concentration of an inhibitor adjusts the metal removal rate by protecting the metal from static etch. Advantageously, the solution contains 0.02 to 5 weight percent inhibitor for inhibiting static etch of copper or silver interconnects. The inhibitor may consist of a mixture of inhibitors. Azole inhibitors are particularly effective for copper interconnects. Typical azole inhibitors include benzotriazole (BTA), mercaptobenzothiazole (MBT) and tolytriazole (TTA). BTA is a particularly effective inhibitor for copper.

Advantageously, the composition of the present invention comprises a ratio of imidazole to the inhibitor (e.g. BTA) of at least 3 to 1 to effectively remove the copper. More preferably, the composition comprises a ratio of imidazole to the inhibitor of at least 10 to 1 to effectively remove the copper. Most preferably, the composition comprises a ratio of imidazole to the inhibitor of at least 25 to 1 to effectively remove the copper.

In addition to the inhibitor, the solution contains 0.05 to 10 weight percent complexing agent for the nonferrous metal. The complexing agent, when present, prevents precipitation of the metal ions formed by dissolving the nonferrous interconnect metals. Most advantageously, the solution contains 0.1 to 5 weight percent complexing agent for the nonferrous metal. Example complexing agents include acetic acid, citric acid, ethyl acetoacetate, glycolic acid, lactic acid, malic acid, oxalic acid, salicylic acid, sodium diethyl dithiocarbamate, succinic acid, tartaric acid, thioglycolic acid, glycine, alanine, aspartic acid, ethylene diamine, trimethyl diamine, malonic acid, gluteric acid, 3-hydroxybutyric acid, propionic acid, phthalic acid, isophthalic acid, 3-hydroxy salicylic acid, 3,5-dihydroxy salicylic acid, gallic acid, gluconic acid, pyrocatechol, pyrogallol, tannic acid, including, salts and mixtures thereof. Advantageously, the complexing agent is selected from the group consisting of acetic acid, citric acid, ethyl acetoacetate, glycolic acid, lactic acid, malic acid, oxalic acid and mixtures thereof. Most advantageously, the complexing agent is citric acid.

Advantageously, the polishing composition contains 0.5 to 40 weight percent abrasive to facilitate barrier layer removal. Within this range, it is desirable to have the abrasive present in an amount of greater than or equal to 1.0 weight percent, and preferably greater than or equal to 2.0 weight percent. Also, desirable within this range is an amount of less than or equal to 25 weight percent, and preferably less than or equal to 20 weight percent. Most preferably, the abrasive concentration is from 10 to 15 weight percent.

The abrasive has an average particle size of less than or equal to 150 nanometers (nm) for preventing excessive metal dishing and dielectric erosion. For purposes of this specification, particle size refers to the average particle size of the abrasive. More preferably, it is desirable to use a colloidal abrasive having an average particle size of less than or equal to 100 nm. Further, minimal dielectric erosion and metal dishing advantageously occurs with colloidal silica having an average particle size of less than or equal to 50 nm. In addition, the preferred colloidal abrasive may include additives, such as dispersants, surfactants and buffers to improve the stability of the colloidal abrasive. One such colloidal abrasive is colloidal silica from Clariant S.A., of Puteaux, France.

The polishing composition includes the abrasive for “mechanical” removal of desired layers. Suitable examples of abrasives include the following: inorganic oxide, inorganic oxides having hydroxide coatings, metal boride, metal carbide, metal nitride, or a combination comprising at least one of the foregoing abrasives. Suitable inorganic oxides include, for example, silica (SiO₂), silica particles coated with aluminum hydrous oxide, ellipsoidal particles of different anisometry coated with silica, silica particles coated with ceria hydroxide particles, alumina (Al₂O₃), titania (TiO₂), zirconia (ZrO₂), ceria (CeO₂), manganese oxide (MnO₂), and combinations comprising at least one of the foregoing inorganic oxides.

Alumina particles have been found to form aluminum silicate. Aluminum silicate is an amphoteric species, which associates with the silica surface. Thus, the aluminum silicate, once formed, tends to stay on the silica surface and protect it. Alumina is available in many forms such as alpha-alumina, gamma-alumina, delta-alumina, and amorphous (non-crystalline) alumina. A suitable example of alumina is boehmite (AlO(OH)). Modified forms of these inorganic oxides such as polymer-coated inorganic oxide particles may also be utilized if desired. Suitable metal carbides, boride and nitrides include, for example, silicon carbide, silicon nitride, silicon carbonitride (SiCN), boron carbide, tungsten carbide, zirconium carbide, aluminum boride, tantalum carbide, titanium carbide, and mixtures comprising at least one of the foregoing metal carbides, boride and nitrides. Diamond may also be utilized as an abrasive if desired. Alternative abrasives also include polymeric particles and coated polymeric particles. The preferred abrasive is colloidal silica.

Advantageously, the composition and method provide excellent controlled polishing of copper. In particular, the aqueous composition of the present invention is useful for “tuning” the removal rate of the copper to suit a desired application. Namely, the present composition can be utilized to accelerate the removal of copper from a semiconductor wafer while minimizing corrosion problems. The composition utilizes a known inhibitor for copper, imidazole, to unexpectedly accelerate the copper removal. In particular, a combination of, or interaction of, inhibitors (e.g., imidazole and BTA) are utilized to accelerate the removal of copper. It is believed that the imidazole “competes” with the BTA for the copper, providing a net increase or acceleration in the copper removal rate, rather than slowing of the removal rate.

The imidazole compounds provide efficacy over a broad pH range in solutions containing a balance of water. This solution's useful pH range extends from at least 2 to 13. In addition, the solution advantageously relies upon a balance of deionized water to limit incidental impurities. The pH of the polishing fluid of this invention is preferably from 7 to 12, more preferably from pH 7.5 to 10. The bases used to adjust the pH of the slurry of this invention may be a base containing ammonium ion, such as ammonium hydroxide, bases containing alkyl-substituted ammonium ions, bases containing alkali metal ion, bases containing alkali-earth metal ion, bases containing group IIIB metal ion, bases containing group IVB metal ion, bases containing group VB metal ion and salts containing transition metal ion. The designed pH in the basic range is not only for removal of the barrier surface, but also helpful for the slurry of this invention to be stable. For the polishing slurry, the pH may be adjusted by a known technique. For example, an alkali may be directly added to a slurry in which a silica abrasive is dispersed and an organic acid is dissolved. Alternatively, a part or all of an alkali to be added may be added as an organic alkali salt. Examples of an alkali, which may be used, include alkali metal hydroxides such as potassium hydroxide, alkali metal carbonates such as potassium carbonate, ammonia and amines.

Optionally, the solution contains 0 to 10 weight percent oxidizer. Advantageously, the optional oxidizer is in the range of 0.01 to 5 weight percent. The oxidizing agent can be at least one of a number of oxidizing compounds, such as hydrogen peroxide (H₂O₂), monopersulfates, iodates, magnesium perphthalate, peracetic acid and other per-acids, persulfates, bromates, periodates, nitrates, iron salts, cerium salts, Mn (III), Mn (IV) and Mn (VI) salts, silver salts, copper salts, chromium salts, cobalt salts, halogens hypochlorites and a mixture thereof. Furthermore, it is often advantageous to use a mixture of oxidizer compounds. When the polishing slurry contains an unstable oxidizing agent such as, hydrogen peroxide, it is often most advantageous to mix the oxidizer into the slurry at the point of use.

Optionally, the novel polishing composition may contain about 0 to 10 weight percent of a thermoplastic polymer. Preferably, the composition contains about 0.05 to 2 weight percent of a thermoplastic polymer. Also, the thermoplastic polymers have weight average molecular weights of 1,000 to 1,000,000 grams/mole as determined by gel permeation chromatography (GPC). In one embodiment, the thermoplastic polymers have weight average molecular weights of 3,000 to 500,000 grams/mole. In another embodiment, the thermoplastic polymers have weight average molecular weights of 5,000 to 100,000 grams/mole. In yet another embodiment, the thermoplastic polymers have weight average molecular weights of 10,000 to 30,000 grams/mole.

Exemplary thermoplastic polymers that may be used in the polishing composition are oligomers, polymers, ionomers, dendrimers, copolymers such as block copolymers, graft copolymers, star block copolymers, random copolymers, or the like, or combinations comprising at least one of the foregoing polymers. Suitable examples of thermoplastic polymers that can be used in the polishing composition are polyacetals, polyacrylics, polycarbonates polystyrenes, polyesters, polyamides, polyamideimides, polyarylates, polyarylsulfones, polyethersulfones, polyphenylene sulfides, polysulfones, polyimides, polyetherimides, polytetrafluoroethylenes, polyetherketones, polyether etherketones, polyether ketone ketones, polybenzoxazoles, polyoxadiazoles, polybenzothiazinophenothiazines, polybenzothiazoles, polypyrazinoquinoxalines, polypyromellitimides, polyquinoxalines, polybenzimidazoles, polyoxindoles, polyoxoisoindolines, polydioxoisoindolines, polytriazines, polypyridazines, polypiperazines, polypyridines, polypiperidines, polytriazoles, polypyrazoles, polycarboranes, polyoxabicyclononanes, polydibenzofurans, polyphthalides, polyacetals, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polysilazanes, or the like, or combinations comprising at least one of the foregoing thermoplastic polymers. A preferred thermoplastic polymer is polyvinyl alcohol. An exemplary weight average molecular weight for a polyvinylalcohol thermoplastic polymer is about 13,000 to about 23,000 grams/mole.

Additionally, blends of thermoplastic polymers may also be used. Examples of blends of thermoplastic polymers include acrylonitrile-butadiene-styrene/nylon, polycarbonate/acrylonitrile-butadiene-styrene, acrylonitrile butadiene styrene/polyvinyl chloride, polyphenylene ether/polystyrene, polyphenylene ether/nylon, polysulfone/acrylonitrile-butadiene-styrene, polycarbonate/thermoplastic urethane, polycarbonate/polyethylene terephthalate, polycarbonate/polybutylene terephthalate, thermoplastic elastomer alloys, nylon/elastomers, polyester/elastomers, polyethylene terephthalate/polybutylene terephthalate, acetal/elastomer, styrene-maleicanhydride/acrylonitrile-butadiene-styrene, polyether etherketone/polyethersulfone, polyethylene/nylon, polyethylene/polyacetal, and the like, and mixtures comprising at least one of the foregoing blends of thermoplastic polymers.

As an option to the thermoplastic polymer, the novel polishing composition may contain about 0 to 10 weight percent of polyvinylpyrrolidone. In one embodiment, the polyvinylpyrrolidone is present in an amount of about 0.01 to about 5 weight percent. In another embodiment, the polyvinylpyrrolidone is present in an amount of about 0.1 to about 2 weight percent. The weight average molecular weight of polyvinylpyrrolidone is 100 to 1,000,000 grams/mole as determined by GPC. In one embodiment, the polyvinylpyrrolidone has a weight average molecular weight of 500 to 500,000 grams/mole. In another embodiment, the polyvinylpyrrolidone has a weight average molecular weight of 1,000 to 250,000 grams/mole. In yet another embodiment, the polyvinylpyrrolidone has a weight average molecular weight of 5,000 to 100,000 grams/mole. An exemplary weight average molecular weight for the polyvinylpyrrolidone polymer is about 8,000 to about 12,000 grams/mole, with a weight average molecular weight of 10,000 grams/mole being most preferred.

Optionally, a mixture of polyvinylpyrrolidone and the thermoplastic polymer may be utilized, rather than the polyvinylpyrrolidone or the thermoplastic polymer alone. Advantageously, it is desirable to utilize the polyvinylpyrrolidone and thermoplastic polymer in a weight ratio of 1:10 to 100:1 respectively. In one embodiment, it is desirable to utilize the polyvinylpyrrolidone and thermoplastic polymer in a weight ratio of 1:5 to 50:1 respectively. In another embodiment, it is desirable to utilize the polyvinylpyrrolidone and thermoplastic polymer in a weight ratio of 1:5 to 60:1 respectively. In yet another embodiment, it is desirable to utilize the polyvinylpyrrolidone and thermoplastic polymer in a weight ratio of 1:3 to 10:1 respectively. Preferred mixtures include, polyvinylpyrrolidone, and polyvinyl alcohol.

Although the polishing fluid of the present invention is particularly effective in removing copper, the present invention is also applicable to any semiconductor substrate containing a conductive metal, such as aluminum, tungsten, platinum, palladium, gold, or iridium; a barrier or liner film, such as tantalum, tantalum nitride, titanium, or titanium nitride; and an underlying dielectric layer. For purposes of the specification, the term dielectric refers to a semi-conducting material of dielectric constant, k, which includes low-k and ultra-low k dielectric materials. The present method removes copper with little effect on conventional dielectrics and low-k dielectric materials as well as tantalum barrier materials. The solution and method are excellent for preventing erosion of multiple wafer constituents, for example, porous and nonporous low-k dielectrics, organic and inorganic low-k dielectrics, organic silicate glasses (OSG), fluorosilicate glass (FSG), carbon doped oxide (CDO), tetraethylorthosilicate (TEOS) and a silica derived from TEOS.

The polishing solution may also include levelers such as, ammonium chloride, to control surface finish of the interconnect metal. In addition to this, the solution optionally may contain a biocide for limiting biological contamination. For example, Kordek® MLX microbicide 2-Methyl-4-isothiazolin-3-one in water (Rohm and Haas Company) provides an effective biocide for many applications. The biocide is typically used in the concentration prescribed by the supplier.

The composition and method provide excellent controlled polishing of copper. In particular, the copper removal agent of the present invention is useful for “tuning” the removal rate of the copper to suit a desired application. Namely, the present composition can be utilized to accelerate the removal of copper from a semiconductor wafer. The composition utilizes a known inhibitor for copper to unexpectedly accelerate the copper removal.

### EXAMPLES

In the Examples, numerals represent examples of the invention and letters represent comparative examples. All example solutions contained 0.005 weight percent Kordek® MLX microbicide 2-Methyl-4-isothiazolin-3-one in water and 0.01 weight percent ammonium chloride brightener. In addition, all example solutions contained 0.3 weight percent citric acid, 0.2 weight percent polyvinylpyrrolidone and 0.8 percent hydrogen peroxide.

### Example 1

This experiment measured removal rates of the tantalum nitride barrier, a dielectric layer of carbon doped oxide and copper from a semiconductor wafer. In particular, the test determined the effect of the addition of imidazole to the removal rates of copper in a second step polishing operation, as a function of the concentration of the BTA. A Strausbaugh polishing machine using a Politex polyurethane polishing pad (Rodel, Inc.) under downforce conditions of about 1.5 psi and a polishing solution flow rate of 200 cc/min, a platen speed of 93 RPM and a carrier speed of 87 RPM planarized the samples. The polishing solutions had a pH of 9 adjusted with KOH and HNO₃. All solutions contained deionized water. In addition, polishing solutions included 12 weight percent silica abrasives having an average particle size of 50 nm.

TABLE 1
Second Step Polishing Results

| | Imidazole | BTA | Cu | CDO | TaN | Ratio |
|---|---|---|---|---|---|---|
| Test | (wt %) | (wt %) | (Å/min) | (Å/min) | (Å/min) | Imidazole/BTA |
| A | — | 0.05 | 192 | 205 | 884 | — |
| 1 | 0.10 | 0.02 | 199 | 196 | 893 | 5 |
| 2 | 0.50 | 0.02 | 495 | 182 | 912 | 25 |
| 3 | 1.00 | 0.02 | 669 | 177 | 979 | 50 |
| 4 | 0.10 | 0.05 | 167 | 191 | 928 | 2 |
| 5 | 0.50 | 0.05 | 233 | 213 | 939 | 10 |
| 6 | 1.00 | 0.05 | 333 | 219 | 972 | 20 |
| 7 | 0.10 | 0.035 | 201 | 174 | 848 | 3 |
| 8 | 0.50 | 0.035 | 327 | 217 | 867 | 14 |
| 9 | 1.00 | 0.035 | 424 | 220 | 918 | 29 |

As illustrated in Table 1, the addition of imidazole to the slurry generally improved the removal rate of the copper. In particular, the removal rate of the copper was accelerated when the ratio of the weight percent of the imidazole to the BTA was at least 3 to 1. Tests 1-3, the polishing rate of the copper improved from 199 to 669 Å/min as the weight percent of the imidiazole was increased from 0.10 to 1.00 as the BTA was kept constant at 0.02 weight percent. Similarly, in Tests 4-6, the polishing rate of the copper improved from 167 to 333 Å/min as the weight percent of the imidiazole was increased from 0.10 to 1.00 as the BTA was kept constant at 0.05 weight percent. Also, in Tests 7-9, the polishing rate of the copper improved from 201 to 424 Å/min as the weight percent of the imidiazole was increased from 0.10 to 1.00 as the BTA was kept constant at 0.035 weight percent. The polishing rate of the copper was not accelerated when the ratio of the weight percent of the imidazole to the BTA was 2 to 1. The polishing rates of the carbon doped oxide and the tantalum nitride were relatively unaffected by the addition of the imidazole.

### Example 2

In this experiment, the static etch rate of the copper with the addition of imidazole was measured with a static electrochemical cell. All example solutions were the same as Example 1 above. The slurry static etch rate (Å/min) was determined from the calculated average Ecorr/Icorr values of the test samples.

TABLE 2

| | Imidazole | Avg. Ecorr | Avg Icorr | Static Etch |
|---|---|---|---|---|
| Test | (wt %) | (mV) | (uA/Cm2) | (Å/min) |
| A | 0 | 231 | 1.63 | 0.36 |
| 1 | 0.1 | 240 | 1.87 | 0.41 |
| 2 | 0.8 | 250 | 2.81 | 0.62 |

As illustrated in Table 2 above, as the concentration of the imidazole increased, there was an increase in the copper static etch rate. In particular, the static etch rate was increase to 0.62 Å/min from 0.36 Å/min when 0.8 weight percent of the imidazole was added to the Test sample A which contained 0 weight percent imidazole. Additionally, the static etch rate was within acceptable rates to avoid corrosion problems.

1. An aqueous composition useful for polishing copper on a semiconductor wafer comprising by weight percent 0.001 to 6 inhibitor for a nonferrous metal, 0.05 to 10 complexing agent for the metal, 0.01 to 25 copper removal agent for accelerating the removal of the copper, 0.5 to 40 abrasive, 0 to 10 selected from the group comprising, polyvinylpyrrolidone, thermoplastic polymer and mixtures thereof, wherein the copper removal agent is imidazole.

2. The composition of claim 1 wherein the imidazole is a compound of a formula selected from the group comprising: 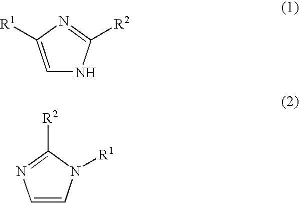
wherein, R¹ and R² are selected from the group comprising a hydrogen atom, an alkyl group optionally having substituent(s), an unsaturated alkyl group optionally having substituent(s), a cycloalkyl group optionally having substituent(s), an aralkyl group optionally having substituent(s), an arylalkenyl group optionally having substituent(s), an aryl-cyclic hydrocarbon group optionally having substituent(s), an aryl group optionally having substituent(s), a heterocyclic residue optionally having substituent(s) and an alkoxycarbonyl group optionally having substituent(s) and combinations thereof.

3. The composition of claim 1 wherein a ratio of the weight percent of the imidazole to the inhibitor is at least 3 to 1.

4. The composition of claim 1 wherein the weight percent of the imidazole is 0.01 to 5.

5. The composition of claim 1 wherein the inhibitor is benzotriazole.

6. The composition of claim 1 wherein the thermoplastic polymer is polyvinyl alcohol.

7. The composition of claim 1 wherein the aqueous composition has a pH of 7.5 to 10.

8. An aqueous composition useful for polishing copper on a semiconductor wafer comprising by weight percent 0.001 to 6 benzotriazole to inhibit corrosion of the copper, 0.05 to 10 complexing agent for the copper, 0.01 to 25 imidazole for accelerating the polishing of the copper, 0.5 to 40 abrasive, 0 to 10 oxidizer and 0 to 10 selected from the group comprising, polyvinylpyrrolidone, polyvinyl alcohol and mixtures thereof and balance water, wherein a weight percent ratio of the imidazole to the benzotriazole is at least 3 to 1.

9. A method for polishing copper from a semiconductor wafer comprising:
contacting the wafer with a polishing composition, the wafer containing the copper, the polishing composition comprising by weight percent 0.001 to 6 inhibitor for a nonferrous metal, 0.05 to 10 complexing agent for the metal, 0.01 to 25 imidazole, 0.5 to 40 abrasive, 0 to 10 oxidizer, 0 to 10 selected from the group comprising, polyvinylpyrrolidone, polyvinyl alcohol and mixtures thereof and balance water; and
polishing the wafer with a polishing pad, wherein the imidazole accelerates the polishing of the copper.

10. The method of claim 9 wherein the imidazole is a compound of a formula selected from the group comprising: 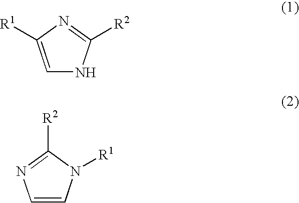
wherein, R¹ and R² are selected from the group comprising a hydrogen atom, an alkyl group optionally having substituent(s), an unsaturated alkyl group optionally having substituent(s), a cycloalkyl group optionally having substituent(s), an aralkyl group optionally having substituent(s), an arylalkenyl group optionally having substituent(s), an aryl-cyclic hydrocarbon group optionally having substituent(s), an aryl group optionally having substituent(s), a heterocyclic residue optionally having substituent(s) and an alkoxycarbonyl group optionally having substituent(s) and combinations thereof.
